(19) United States
(12) Patent Application Publication
(10) Pub. No.: US 2022/0376636 A1
(43) Pub. Date: Nov. 24, 2022

(54) PIEZOELECTRIC ENERGY HARVESTING SYSTEM FOR USE IN VEHICLE

(71) Applicant: VOLVO TRUCK CORPORATION, Göteborg (SE)

(72) Inventors: Antriksh SHINDE, Maharashtra (IN); Anumodh RAJAN, Karnataka (IN)

(73) Assignee: VOLVO TRUCK CORPORATION, Göteborg (SE)

(21) Appl. No.: 17/755,286

(22) PCT Filed: Oct. 13, 2020
(86) PCT No.: PCT/EP2020/078787

§ 371 Date: Apr. 26, 2022

(30) Foreign Application Priority Data
Nov. 11, 2019 (IN) 201941045845

(51) Int. Cl. H02N 2/18; H01L 41/113; H02J 7/32

(52) U.S. Cl. CPC H02N 2/183; H02N 2/186; H02N 2/181; H01L 41/113; H02J 7/32

(57) ABSTRACT

The invention relates to a piezoelectric energy harvesting system (10) configured to be installed on a vehicle (1), characterized in that the system (10) comprises: —an inner panel (12); —an outer panel (14) slidably movable relative to the inner panel (12); —at least one deformable piezoelectric element (16) disposed between the inner panel (12) and the outer panel (14), said piezoelectric element (16) being capable of producing electrical power when it is deformed; —a plurality of impact elements (18) fixedly connected to the outer panel (14) and adapted to apply a compression force on the at least one piezoelectric element (16) when the outer panel (14) and the inner panel (12) are close enough to each other, said compression force causing a mechanical deformation of the at least one piezoelectric element (16); —repulsion means (22) adapted to move the outer panel (14) away from the inner panel (12); —an electrical power storage unit (24); —a one-way electrical circuit (26) connecting the at least one piezoelectric element (16) to the electrical power storage unit (24), said one-way electrical circuit (26) being adapted to charge the electrical power storage unit (24) with the electrical power produced by the at least one piezoelectric element (16) while preventing the application of an electrical charge to the at least one piezoelectric element (16) from the electrical power storage unit (24).

### TECHNICAL FIELD

The invention relates to a piezoelectric energy harvesting system configured to be installed on a vehicle.

The invention can be applied in heavy-duty vehicles, such as trucks, buses and construction equipment. Although the invention will be described with respect to a truck, the invention is not restricted to this particular vehicle, but may also be used in other vehicles such as buses, construction equipment and passenger cars. The invention may also be used on other transportation means such as ships, boats, aeroplanes and any vehicles which may be impacted by winds.

### BACKGROUND

Renewable and clean energy sources have become an increased area of interest due to the energy crisis and the environmental concerns associated with the use of fossil fuels. The global electricity demand is expected to increase by almost 80% in the next decades. A clean energy revolution is required to come out of the fossil fuel dependence.

In recent years, alternatives to fossil fuels have been proposed. In particular, electric or hybrid vehicles are increasingly developed. However, electric vehicles suffer from a limited autonomy, as batteries must be recharged frequently. Generally, the battery recharging can only be done in specific charging stations. During the recharging operation, its owner cannot use the vehicle. The existing methods for recharging the battery of an electric vehicle are therefore not satisfactory.

There is thus a need for a new charging method avoiding the above mentioned problems.

A solution may consist in installing an onboard electrical energy harvesting system that can generate electric energy and charge this energy in the battery of the vehicle.

The existing onboard electrical energy harvesting systems generally use solar panels that are fixed on external parts of the vehicle. However, the energy produced by such solar panels are generally low. Furthermore, these solar panels are not useful during night and cloudy environments.

### SUMMARY

An object of the invention is to provide an electrical energy harvesting system that can be installed on a vehicle for charging its battery.

The object is achieved by a system according to claim 1. Thus, the object is achieved by a piezoelectric energy harvesting system configured to be installed on a vehicle, the system comprising:
an inner panel;
an outer panel slidably movable relative to the inner panel;
at least one deformable piezoelectric element disposed between the inner panel and the outer panel, said piezoelectric element being capable of producing electrical power when it is deformed;
a plurality of impact elements fixedly connected to the outer panel and adapted to apply a compression force on the at least one piezoelectric element when the outer panel and the inner panel are close enough to each other, said compression force causing a mechanical deformation of the at least one piezoelectric element;
repulsion means adapted to move the outer panel away from the inner panel;
an electrical power storage unit;
a one-way electrical circuit connecting the at least one piezoelectric element to the electrical power storage unit, said one-way electrical circuit being adapted to charge the electrical power storage unit with the electrical power produced by the at least one piezoelectric element while preventing the application of an electrical charge to the at least one piezoelectric element from the electrical power storage unit.

Thus configured, the system of the present invention permits to convert kinetic energy due to the wind impacting on the outer panel into electric power to be used for operating a vehicle. The outer panel may advantageously define an external part of the vehicle, such as a wind deflector or a door panel.

The system of the present invention also permits to generate electrical energy in rainy conditions when water droplets impacting on the outer panel causes this outer panel to move closer to the inner panel, thus causing a mechanical deformation of the piezoelectric element leading to the generation of electrical energy. The system of the present invention thus permits to generate electrical energy even when the vehicle is stationary.

The system of the present invention also permits to generate electrical energy when the vehicle is subject to vibrations caused, for example, by the uneven terrain on which the vehicle is travelling. Such vibrations cause the outer panel to move closer to the inner panel, thus causing a mechanical deformation of the piezoelectric element leading to the generation of electrical energy.

Further advantages and advantageous features of the invention are disclosed in the following description and in the dependent claims.

### BRIEF DESCRIPTION OF THE DRAWINGS

With reference to the appended drawings, below follows a more detailed description of embodiments of the invention cited as examples.

In the drawings:

FIG. 1 is a schematic side view of a cab of a truck comprising a piezoelectric energy harvesting system according to the present invention;

FIG. 2a is a schematic side view of a first embodiment of the system according to the invention in a normal state;

FIG. 2b is a view similar to FIG. 2a in a compressed state;

FIG. 3a is a schematic side view of a second embodiment of the system according to the invention in a normal state;

FIG. 3b is a view similar to FIG. 3a in a compressed state;

FIG. 4a is a schematic side view of a third embodiment of the system according to the invention in a normal state;

FIG. 4b is a view similar to FIG. 4a in a compressed state;

FIG. 5 is an enlarged view of the detail of construction of the system shown in FIG. 2a.

### DETAILED DESCRIPTION OF EXAMPLE EMBODIMENTS OF THE INVENTION

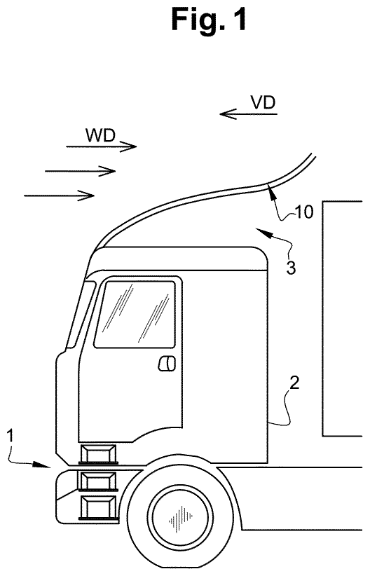

FIG. 1 shows a schematically side view of the front end of a truck 1 being equipped with a piezoelectric energy harvesting system according to the present invention. As illustrated, the truck 1 has a driver's cab 2 on which is mounted a wind deflector 3. The wind deflector 3 is mounted at the roof of the driver's cab 2 so that, when the truck 1 is moving in a direction VD, an airflow flowing in an opposite direction WD hits the curved outer surface of the wind deflector 3. This curved outer surface supports the system 10 of the present invention. Thus, due to the relative velocity of the airflow with respect to the vehicle, the airflow transfers on the system 10 a kinetic energy that is converted into electric power by the system 10.

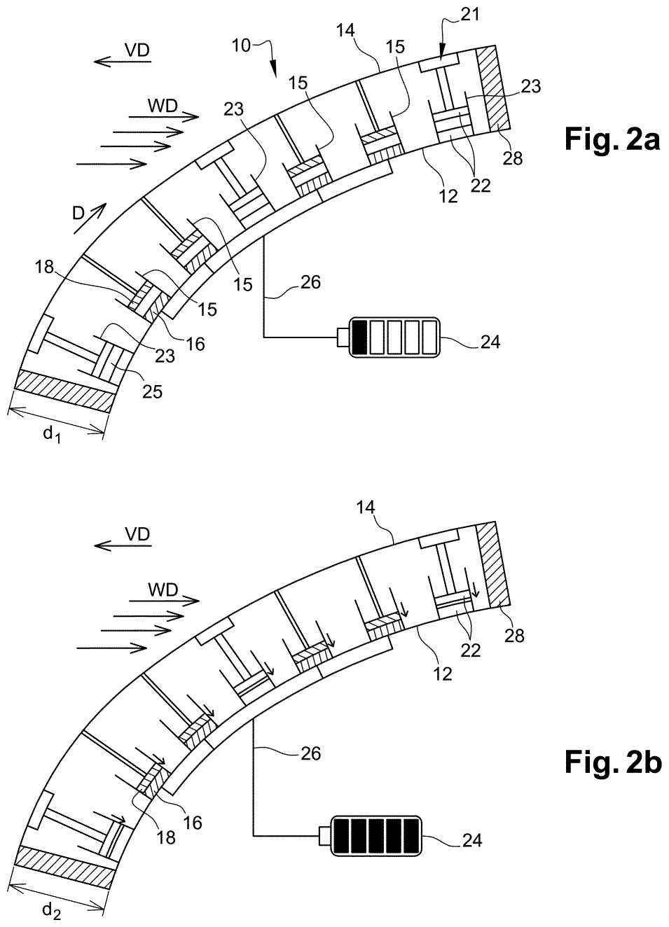

FIG. 2a and FIG. 2b illustrate a first embodiment of the piezoelectric energy harvesting system of the invention. In this first embodiment, the piezoelectric energy harvesting system 10 comprises an inner panel 12 and an outer panel 14 that is slidably movable relative to the inner panel 12. The outer panel 14 may advantageously define the curved outer surface of the wind deflector 3 of the truck 1. The inner and outer panels 12, 14 may advantageously be separated along their side ends with sealing elements 28, said sealing elements 28 preventing any entrance of fluid between the inner and outer panels 12, 14.

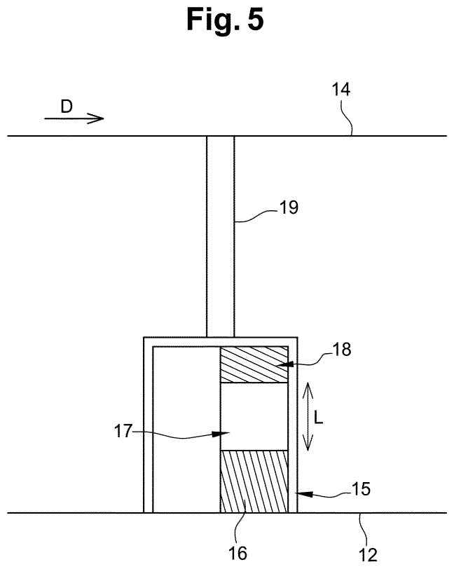

The inner periphery of the inner panel 12 that is oriented towards the outer panel 14 supports a plurality of first hollow cylindrical elements 15 distant from each other along a front-to-rear direction D. As illustrated in detail in FIG. 5, each first cylindrical element 15 is oriented in a substantially perpendicular direction relative to the front-to-rear direction D and defines an housing for a piezoelectric disc-shaped plate 16 fixedly mounted at a bottom part thereof, the thickness of the piezoelectric plate 16 being configured to leave a free space 17 inside the first cylindrical element 15. This free space 17 is adapted to receive a disc-shaped impact element 18, said impact element 18 being fixedly connected to the outer panel 14 via a crosspiece 19. The piezoelectric plate 16 and the impact element 18 may advantageously define the same axial direction, said axial direction being substantially perpendicular to the front-to-rear direction D.

The inner periphery of inner panel 12 also supports a plurality of second hollow cylindrical elements 23 distant from each other along the front-to-rear direction D. Each second cylindrical element 23 is oriented in a substantially perpendicular direction relative to the front-to-rear direction D and defines an housing for a first disc-shaped magnet 22 fixedly mounted at a bottom part thereof, the thickness of this first magnet 22 being configured to leave a free space 25 inside the second cylindrical element 23. This free space 25 is adapted to receive a second disc-shaped magnet 22, said second magnet 22 being fixedly connected to the outer panel 14 via a crosspiece 21. The first and second magnets 22 may advantageously define the same axial direction, said axial direction being substantially perpendicular to the front-to-rear direction D. The first and second magnets 22 are advantageously configured to produce a repulsion force when they get closer to each other. For example, the pole north, or south, of the first magnet 22 may be oriented towards the pole north, or south, of the second magnet 22.

In a normal state illustrated in FIG. 2a, the inner and outer panels 12, 14 are distant from each other by a distance d1. This normal state occurs for example when the truck 1 is stopped or is running at low speed or in the absence of wind. When the truck 1 is moving at medium or high speed in the direction VD, the airflow flowing in the opposite direction WD impacts the outer panel 14 and applies a compression force thereon. Thus, the outer panel 14 tends to get closer to the inner panel 12, which leads to the compressed state illustrated in FIG. 2b. In this compressed state, the distance d2 between the inner and outer panels 12, 14 is lower than the distance d1. When the truck 1 slows down or when the action of the wind decreases, the outer panel 14 returns back to the position illustrated in FIG. 2a under the action of the magnets 22. Thus, under the action of compression forces applied by the wind and repulsive forces applied by the magnets, the transfer of the system 10 between its normal state and its compressed state will be cyclic in nature.

During the displacement of the outer panel 14 from the position illustrated in FIG. 2a to the position illustrated in FIG. 2b, the distant L between the impact element 18 and the piezoelectric plate 16 in each first cylindrical element 15 decreases till the impact element 18 comes into contact with the piezoelectric plate 16. This contact leads to a compression force applied to the piezoelectric plate 16, which causes a mechanical deformation of said piezoelectric plate 16. The mechanical deformation of the piezoelectric plate 16 produces electrical energy. This electrical energy is transmitted to an electrical power storage unit 24 via a one-way electrical circuit 26, said one-way electrical circuit 26 being configured to prevent the application of an electrical charge to the piezoelectric plates 16 from the electrical power storage unit 24. For example, diodes may advantageously be used in the one-way electrical circuit 26. The electrical energy transmitted by the one-way electrical circuit 26 is then stored in the electrical power storage unit 24.

The piezoelectric plates 16 may advantageously be formed of piezoelectric crystals such as quartz, tourmaline, topaz, cane sugar, Rochelle salt or any material that exhibits similar behaviour.

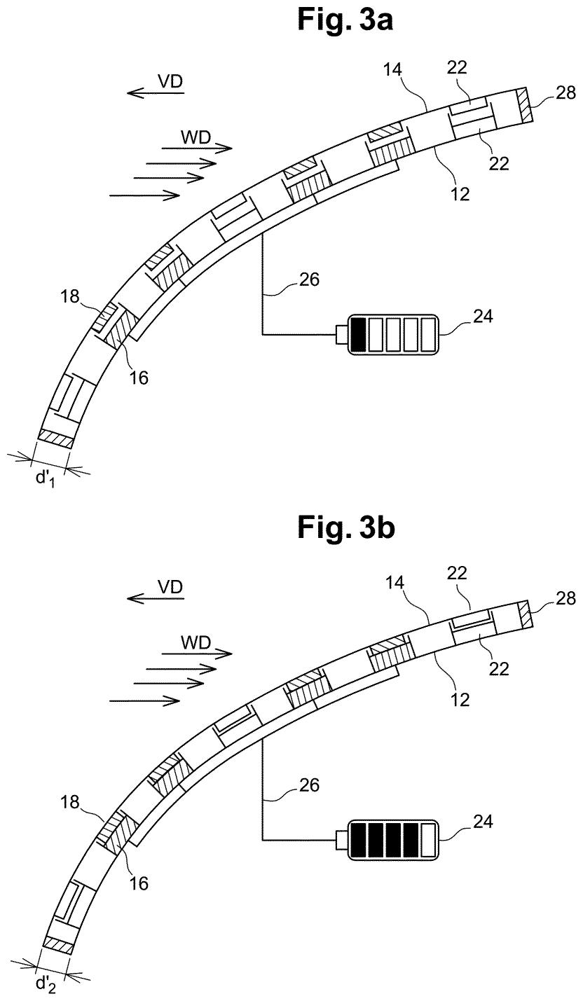

FIG. 3a and FIG. 3b illustrate a second embodiment of the piezoelectric energy harvesting system of the invention. This second embodiment differs from the first embodiment by the fact that the impact elements 18 and the second magnets 22 are directly connected to the outer panel 14. The distances d1′ and d2′ between the outer panel 14 and the inner panel 12 respectively in the normal state and compressed state of the system may thus be lower than the distances d1 and d2.

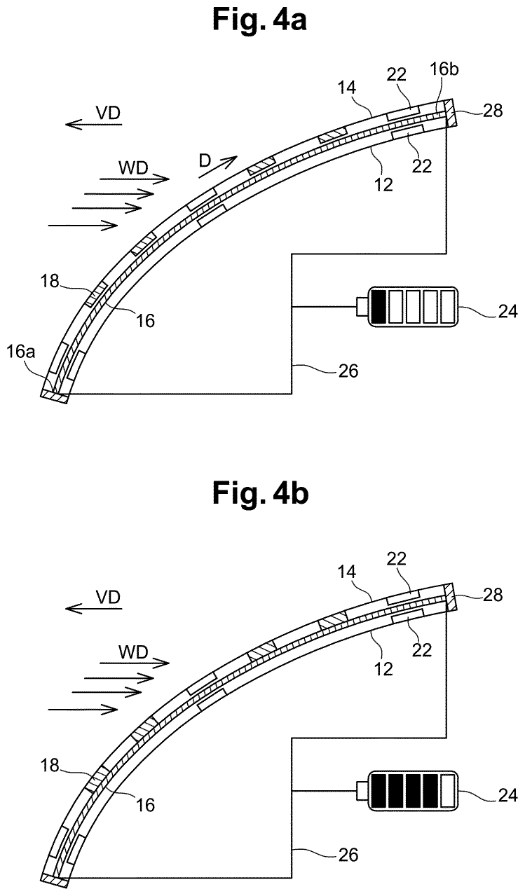

FIG. 4a and FIG. 4b illustrate a third embodiment of the piezoelectric energy harvesting system of the invention. In this third embodiment, the piezoelectric energy harvesting system 10 comprises an inner panel 12 and an outer panel 14 that is slidably movable relative to the inner panel 12. The inner and outer panels 12, 14 may advantageously be separated along their side ends with sealing elements 28, said sealing elements 28 preventing any entrance of fluid between the inner and outer panels 12, 14.

The inner periphery of the outer panel 14 that is oriented towards the inner panel 12 supports a plurality of disc-shaped impact elements 18 distant from each other along a front-to-rear direction D. A curved-shaped piezoelectric strip 26 extends between a first end 16a and a second end 16b, and is parallel to the inner and outer panels 12, 14 and distant thereto. Furthermore, the inner periphery of the inner panel 12, respectively of the outer panel 14, supports a plurality of first disc-shaped magnets 22, respectively a plurality of second disc-shaped magnets 22, distant from each other along the front-to-rear direction D. The first and second magnets 22 may advantageously define per pair the same axial direction, said axial direction being substantially perpendicular to the front-to-rear direction D. The first and second magnets 22 are advantageously configured to produce a repulsion force when they get closer to each other. The piezoelectric strip 26 is disposed between said first and second magnets 22 and distant thereto.

During the displacement of the outer panel 14 from the position illustrated in FIG. 4a, corresponding to the normal state of the system, to the position illustrated in FIG. 4b, corresponding to the compressed state of the system, the distant between the impact elements 18 and the piezoelectric strip 16 decreases till the impact elements 18 come into contact with the piezoelectric strip 16. This contact leads to a compression force applied to the piezoelectric strip 16, which causes a mechanical deformation of said piezoelectric strip 16. The mechanical deformation of the piezoelectric strip 16 produces electrical energy. This electrical energy is transmitted to an electrical power storage unit 24 via a one-way electrical circuit 26, said one-way electrical circuit 26 being configured to prevent the application of an electrical charge to the piezoelectric strip 16 from the electrical power storage unit 24. The electrical energy transmitted by the one-way electrical circuit 26 is then stored in the electrical power storage unit 24. The outer panel 14 returns back to the position illustrated in FIG. 4a under the action of the magnets 22 and when the action of the wind in the direction WD decreases.

In a further embodiment (not shown) of the piezoelectric energy harvesting system of the invention, the system further comprises a heating coil that is disposed between the inner panel 12 and the outer panel 14. This heating coil is adapted to provide heat inside the internal space defined between said inner and outer panels 12, 14. This heating coil may thus avoid that ice builds up on the panels 12, 14 when the system is used in extreme cold conditions.

It is to be understood that the present invention is not limited to the embodiments described above and illustrated in the drawings; rather, the skilled person will recognize that many changes and modifications may be made within the scope of the appended claims.

In particular, the shape of the impact elements 18 and/or of the magnets 22 may be different from a disc. The shape of the inner and outer panels 12, 14 may be straight or may comprise a combination of straight, convex and/or concave shapes. The piezoelectric elements used in the system of the present invention may be different from piezoelectric disc-shaped plates or piezoelectric strips: they may be ring-shaped, tube-shaped or even be made into custom shapes.

Furthermore, the repulsion means 22 that are adapted to move the outer panel 14 away from the inner panel 12 when the action of the wind in the direction WD decreases may be different from magnets and may be chosen among compression springs, gas springs, rubber material, electromechanical actuators, hydraulic actuators, pneumatic actuators, spring loaded slider mechanisms and self-adjusting hydraulic means.

The piezoelectric energy harvesting system 10 of the present invention may also be installed in any vehicles other than a truck, and in any external part of said vehicle other than a wind deflector, for example a hood, a door panel, or a side panel.

1. A piezoelectric energy harvesting system configured to be installed on a vehicle, wherein the system comprises:
an inner panel;
an outer panel slidably movable relative to the inner panel;
at least one deformable piezoelectric element disposed between the inner panel and the outer panel, said piezoelectric element being capable of producing electrical power when it is deformed;
a plurality of impact elements fixedly connected to the outer panel and adapted to apply a compression force on the at least one piezoelectric element when the outer panel and the inner panel are close enough to each other, said compression force causing a mechanical deformation of the at least one piezoelectric element;
repulsion means adapted to move the outer panel away from the inner panel;
an electrical power storage unit;
a one-way electrical circuit connecting the at least one piezoelectric element to the electrical power storage unit, said one-way electrical circuit being adapted to charge the electrical power storage unit with the electrical power produced by the at least one piezoelectric element while preventing the application of an electrical charge to the at least one piezoelectric element from the electrical power storage unit.

2. The system according to claim 1, wherein the at least one piezoelectric element consists in a piezoelectric strip extending between a first end and a second end, parallel to the inner and outer panels.

3. The system according to claim 1, wherein the at least one piezoelectric element comprises a plurality of piezoelectric disc-shaped plates, each piezoelectric disc-shaped plate being fixedly connected to the inner panel so as to face an impact element among the plurality of impact elements, the piezoelectric disc-shaped plates being electrically connected in parallel.

4. The system according to claim 3, wherein each piezoelectric disc-shaped plate forms the bottom part of a cylindrical element, the top part thereof defining a free space inside which the impact element facing the piezoelectric disc-shaped plate can move between a non-contact position, in which said impact element is distant from the piezoelectric disc-shaped plate, and a contact position, in which said impact element is in contact with the piezoelectric disc-shaped plate.

5. The system according to claim 4, wherein each impact element is connected to the outer panel via a crosspiece.

6. The system according to claim 1, wherein the repulsion means are chosen among magnets, compression springs, gas springs, rubber material, electromechanical actuators, hydraulic actuators, pneumatic actuators, spring loaded slider mechanisms and self-adjusting hydraulic means.

7. The system according to claim 1, wherein the system further comprises a heating coil disposed between the inner panel and the outer panel.

8. The system according to claim 1, wherein the at least piezoelectric element is formed of piezoelectric crystals.

9. The system according to claim 1, wherein system further comprises sealing elements disposed between the inner and outer panels along end sides thereof, said sealing elements preventing any entrance of fluid between said inner and outer panels.

10. A vehicle comprising a system according to claim 1.

11. The vehicle according to claim 10, wherein the vehicle is a truck.

12. The vehicle according to claim 10, wherein the system is installed in an external part of the vehicle.

13. The vehicle according to claim 12, wherein the external part is chosen among a wind deflector, a hood, a door panel, and a side panel.
